(19) United States
(12) Patent Application Publication
(10) Pub. No.: US 2010/0059385 A1
(43) Pub. Date: Mar. 11, 2010

(54) METHODS FOR FABRICATING THIN FILM SOLAR CELLS

(76) Inventor: Delin Li, San Jose, CA (US)

Correspondence Address: Delin Li, 797 Firewood Court, San Jose, CA, 95120, US

(21) Appl. No.: 12/554,440

(22) Filed: Sep. 4, 2009

Related U.S. Application Data
(60) Provisional application No. 61/094,890, filed on Sep. 6, 2008.

(51) Int. Cl. C25D 21/12

(52) U.S. Cl. 205/84

(57) ABSTRACT

The present invention relates to CIGS solar cell fabrication. The invention discloses a method for fabricating CIGS thin film solar cells using a roll-to-roll system. The invention discloses method to fabricate semiconductor thin film Cu(InGa)(SeS)₂ by sequentially electroplating a stack comprising of copper, indium, gallium, and selenium elements or their alloys followed by selenization at a temperature between 450 C and 700 C.

The present application is to claim priority to U.S. Provisional Application Ser. No. 61094890 filed on Sep. 6, 2008.

### FIELD OF THE INVENTION

The present invention relates to solar cell manufacture for convert sun energy to electricity.

### BACKGROUND OF THE INVENTION

Solar cells convert energy from the sun to electricity. It is a renewable energy source that does not contribute to the greenhouse. The most commonly known solar cell is configured as large area of p-n junction formed between n-type and p-type semiconductors. The p-n junction creates a voltage bias. Sunlight comes in many colors comprising of low-energy infrared photons, high-energy ultraviolet, and all of the visible light between. A photon with high enough energy absorbed by an atom can lift an electron to a more excited state and an electron-hole pair is created. If the electron-hole pair is generated within or near this field, it sweeps the electrons toward the n-side and the holes to the p-side. When the sides are connected to an external circuit, a current will flow from the p-side through a possible load to the n-side.

The solar cells are traditionally fabricated using silicon (Si) as a light absorbing which uses wafers of single-crystal or polycrystal silicon with a thickness range of 180-330 um. The wafer goes through several process steps and then be integrated into a module. The solar cell using silicon is expensive due to the high material and process cost. In order to achieve lower cost and improved manufacturability at large scale, thin film technologies have been developed in the last three decades. The main advantage of the thin film solar cell technologies is that they have lower costs than the silicon solar cell. They are typically 100 times thinner than silicon wafer with around 1-3 um thickness of the absorbing layer deposited on relative low cost substrates such as glass, metal foils, and plastics. They could be continuously deposited over large areas at lower temperatures. They can tolerate higher impurities of the raw materials. They can be easily integrated into a monolithic interconnected module. For a reference, the semiconductor thin film thickness of the absorbing layer in a thin film solar cell is around 10 times thinner than a human hair. The thin film solar cell typically consist of 5 to 10 different layers whose functions include reducing resistance, forming the p-n junction, reduce reflection losses, and providing a robust layer for contacting and interconnection between cells.

One of the thin film solar cell technologies is copper indium gallium diselenide (CIGS) which is a most cost effective power generation technology. This is due to the fact that the high efficiency of CIGS solar cells has been achieved with around 1-3 um thin absorbing layer of the Cu(InGa)Se₂. Another advantage is that the CIGS solar cells and module have shown excellent long-term stability in the outdoor field. Additionally, CIGS solar cells show high radiation resistance comparing to crystalline silicon solar cell.

The CIGS solar cell is constructed with Cu(InGa)Se₂/CdS junction in a substrate configuration with a metal such as molybdenum back contact. After forming Cu(InGa)Se₂ absorbing layer on a molybdenum coated substrate and then depositing a n-type CdS layer over the CIGS layer, a junction is formed between Cu(InGa)Se₂ and CdS layers. A transparent ZnO layer is then deposited on the CdS layer and then deposit a front contact layer.

The ratio of the gallium vs copper and indium is critical for solar cell efficiency. Hamda A. Al-Thani, et al (reference #1) reported CIGS thin film solar cells efficiency versus the chemical compositions. The CIGS films were subsequently deposited on the Mo films using different sputtering pressure conditions or fixed physical vapor deposition rates for Cu, Ga, In, and Se. The solar cell efficiency was reported between 12.35% and 15.99%. The copper composition is varied from 23.76 at % to 24.84 at %, indium composition is varied from 17.01 at % to 18.11 at %, gallium composition is varied from 6.38 at % to 7.72 at %, and selenium composition is varied from 50.44 at % to 53.26 at %. It was also reported that the atomic ratio of Ga/(In +Ga) is varied between 0.261 and 0.312.

A wide variety of thin film deposition methods has been used to make Cu(InGa)Se₂ semiconductor layer including vacuum co-evaporation, vacuum sputtering, and electroplating.

Co-evaporation of Cu, In, Ga, and Se from separate targets is one of the widely approaches. One of the methods is co-evaporation of elemental In, Ga and Se on the substrates of Mo-coated substrate followed by co-evaporation of elemental Cu and Se. Another method is vacuum depositing Cu—Ga alloy on metallized substrate followed by vacuum depositing indium to obtain Cu—Ga/In stacks. The stack of the Cu—Ga/In is then selenized at selenium atmosphere to form Cu(InGa)Se₂ semiconductor thin film. Another method is two stage co-evaporation processes. The first step involves the deposition of sequentially copper and Gallium and co-deposition of indium and selenium. This is followed by the second stage where the substrate is annealed in the presence of Selenium and a thin layer of copper is deposited to neutralize the excess Indium and Gallium on the surface to form the CIGS absorber layer. The main issue of the vacuum deposition processes is high equipment cost and low material utilization.

Another technique for growing Cu(InGa)Se₂ semiconductor thin film is electrochemical deposition. In 1983, Bhattacharya (Ref #2, J. Electrochem. Soc, 130, p2040, 1983) demonstrated in the first time that copper-indium-gallium-selenium could be prepared by electrodeposition process. Since then, several researches (References 3-7) have been reported. These researches focused on the co-electrodeposition process.

Three US patents (U.S. Pat. No. 5,871,630; U.S. Pat. No. 5,730,852; and U.S. Pat. No. 5,804,054) by Raghu N. Bhattacharya describe a two steps process for co-electrodeposition of copper-indium-gallium-diselenide film to make solar cell. In the first step, a precursor film of CuInGaSe is electrodeposited on a substrate such as glass coated with molybdenum. The chemical solution used for the CIGS film deposition contains copper, indium, gallium, and selenium so that the Copper-indium-gallium-selenium was co-electrodeposited. The second step is physical vapor deposition of copper, indium, gallium, and selenium to adjust the final composition. The disadvantage of the co-electrodeposition method is that it's hard to control the composition or atomic ratio of the four elements. Therefore the co-electrodeposition method is hard to be used for volume manufacturing.

U.S. Pat. No. 4,581,108 disclosed a process for electrodeposition of copper and indium film followed by selenizing it. A copper layer is electrodeposited on a metallized substrate followed by electro-deposition of indium layer to form a stacked copper-indium layer. The stacked layer is then heated up in selenium atmosphere to form copper-indium-selenium film. This is called the CIS thin film solar cell.

In all of the above deposition methods, the molybdenum (Mo) has been used as a back contact material for CIGS solar cells. Key beneficial features of Mo is that it has high electrical conductivity, low contact resisting to CIGS, and high temperature stability in the presence of selenium during CIGS absorber deposition. However, Mo has an adhesion issue to CIGS layer.

### BRIEF DESCRIPTION OF THE DRAWINGS

FIG. 1 shows a side view of the roll-to-roll fabrication process comprising a copper electroplating unit, an indium electroplating unit, a second copper electroplating unit, a Ga—Se alloy electroplating unit, a Se-alloy electroplating unit, a thickness measurement unit, a parameters control unit, a selenization unit, and a n-type semiconductor thin film CdS deposition unit.

FIG. 2 shows a cross sectional view of the processes for fabricating CIGS solar cells.

FIG. 3 shows a thin film thickness measurement using a non-travelable XRF for a roll-to-roll fabrication line.

FIG. 4 shows a thin film thickness measurement using a travelable XRF for a roll-to-roll fabrication line.

FIG. 5 shows a thin film thickness measurement using travelable multiple XRFs for a roll-to-roll fabrication line.

### SUMMARY OF THE INVENTION

The present invention provides method for fabricating CIGS solar cells using a roll-to-roll system comprising of 1) depositing a back contact electrode, 2) sequentially electroplating a stack comprising of at least one layer of copper, at least one layer of indium, at least one layer of gallium alloy, and at least one layer of selenium alloy, 3) measure and control the thickness of each stack layers, 4) annealing the electroplated stack at a high temperature to form a p-type semiconductor thin film comprising of copper, indium, gallium, selenium, and sulphur elements, 5) depositing a n-type semiconductor layer on the p-type semiconductor layer to form p-n junction, 6) depositing front window layers on the n-type semiconductor layer, and 7) form front electrodes.

One aspect of the present invention provides a method to sequentially electrodeposit a stack comprising of copper, indium, Ga—Se alloy, and Se-alloy followed by selenization at a temperature between 450 C and 700 C to form Cu(InGa)Se₂ or Cu(InGa)(SeS)₂ semiconductor thin films.

In another aspect, the present invention provides method and process for electroplating gallium-selenium (Ga—Se) alloy.

In yet another aspect, the present invention provides a method to electrodeposit Se-alloy.

It is another object of the present invention to provide a method to monitor and control the thickness of the electroplated stack on a roll-to-roll moving substrate.

### DETAIL DESCRIPTION

The present invention relates to solar cells fabrication. In particular, the present invention relates to fabricate copper-indium-gallium-diselenide (CIGS) solar cells. According to embodiments of the present invention, a semiconductor thin film for CIGS solar cells which could convert sunlight to electricity may be fabricated by electroplating followed by selenization. The semiconductor thin film may be fabricated by sequentially electroplating a stack comprising of copper, indium, gallium, and selenium elements or their alloys followed by selenization at a temperature between 450 C and 700 C to form Cu(InGa)Se₂ or Cu(InGa)(SeS)₂ semiconductor thin films.

Based on the present invention, copper, indium, gallium alloy, and selenium alloys may be sequentially electrodeposited as a stack on a metallized substrate. The metalized substrate is a substrate with a metal layer or metals layers of the back contact electrode. The substrates may be one of the materials selected from the group comprising of soda lime glass, aluminum foil, stainless steel foil, titanium foil, molybdenum foil, steel strip, polyimide film, PET film, Teflon film, PEN film, brass, and polyester. For metal substrates, a dielectric material such as SiO₂, Si₃N₄, and Al₂O₃ may be optionally coated on the surface before depositing a metallized back contact electrode. The metal layer or metals layers of the back contact electrode on the substrate may be one of the materials selected from the group consisting of Ti—Cu, Cr—Cu, W—Cu, Mo—Cu, Mo, W, Ti—W, Ti/Pd, Ti/Pt, Mo/Cu, Cr/Pd, Ti/Ag, Ti/Cu, Cr/Cu, and Ti/Au. The Ti—Cu is an alloy that comprises titanium element and copper element. The Cr—Cu is an alloy comprises chromium element and copper element. The W—Cu is an alloy that comprises tungsten element and copper element. The Mo—Cu is an alloy that comprises molybdenum element and copper element. The Ti—W is an alloy that is comprises titanium element and tungsten element. The Mo/Cu is a stack of molybdenum and copper elements. The Ti/Pd is a stack of titanium element and palladium element. The Ti/Pt is a stack of titanium element and platinum element. The Cr/Pd is a stack of chromium element and palladium element. The Ti/Cu is a stack of titanium element and copper element. The Cr/Cu is a stack of chromium element and copper element. The Ti/Ag is a stack of titanium element and silver element. The Ti/Au is a stack of titanium element and gold element.

The sequentially electroplated stack comprises at least one layer of copper, at least one layer of indium, at least one layer of gallium alloy, and at least one layer of selenium alloy. The alloy described above is a material that comprises two or more elements. For example, Ga—Se is an alloy that comprises gallium and selenium elements, Se—Cu is an alloy comprises selenium and copper elements, and Ga—Se—Cu is an alloy that comprises gallium, selenium, and copper elements, et al.

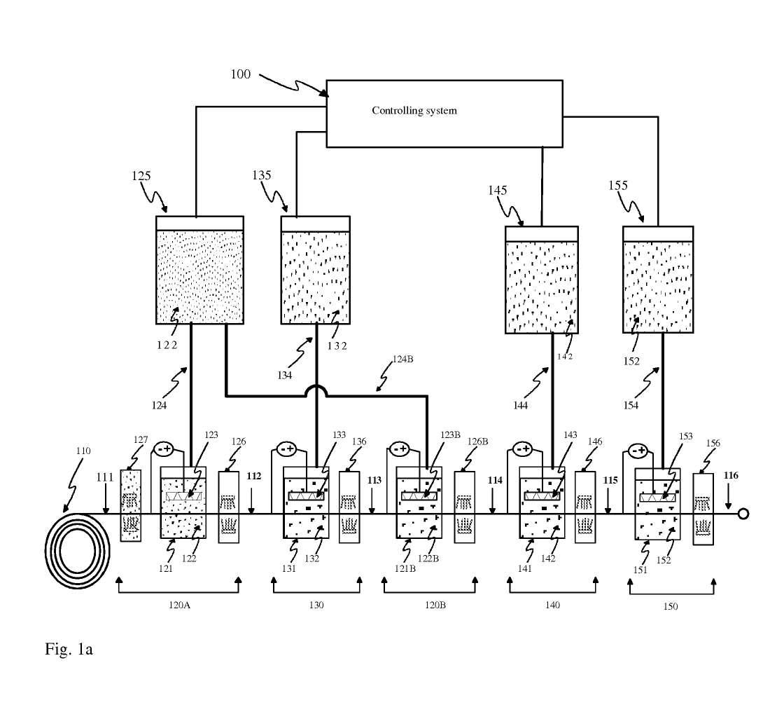

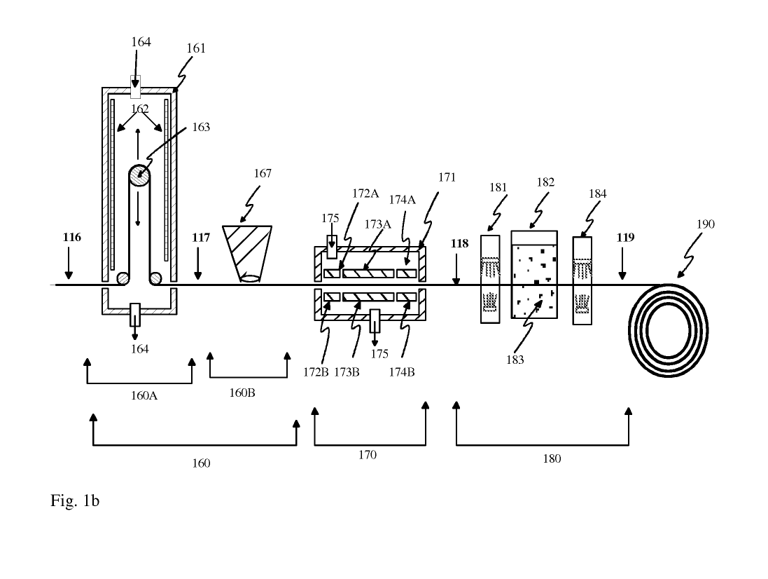

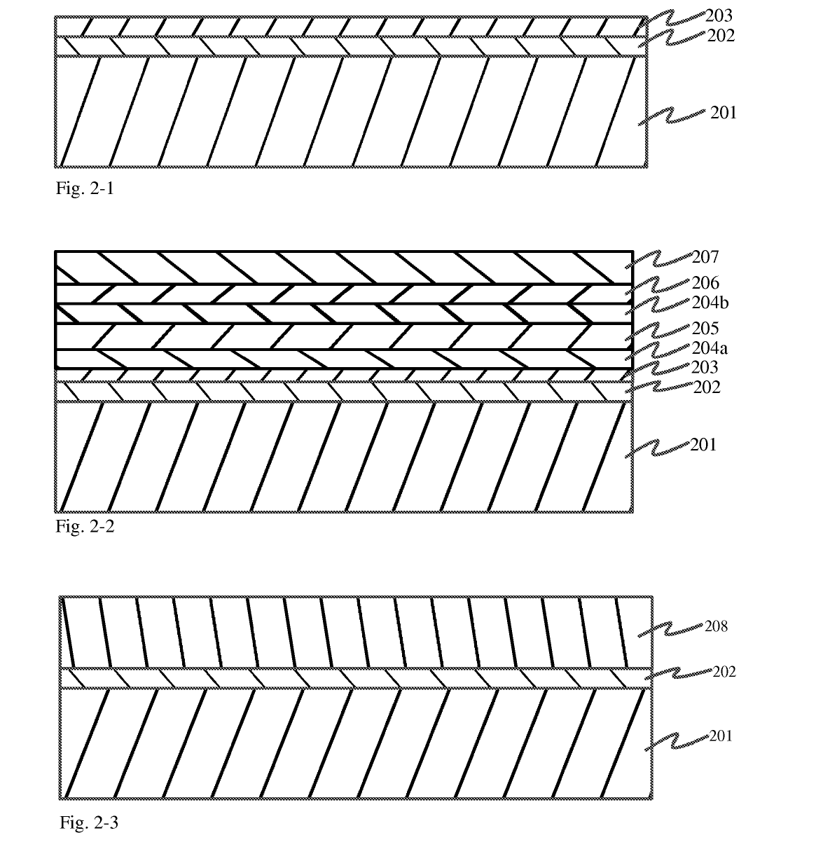

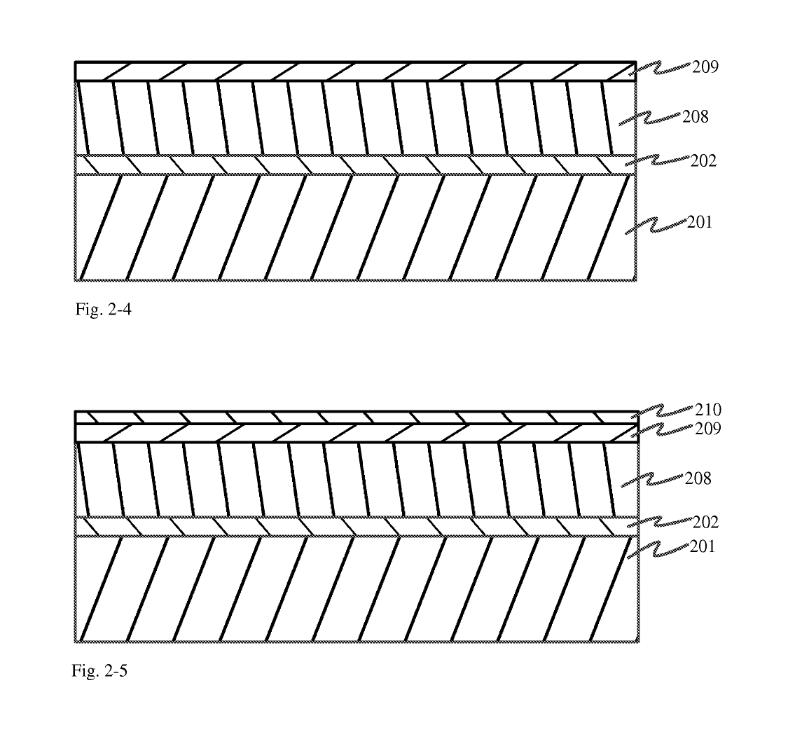

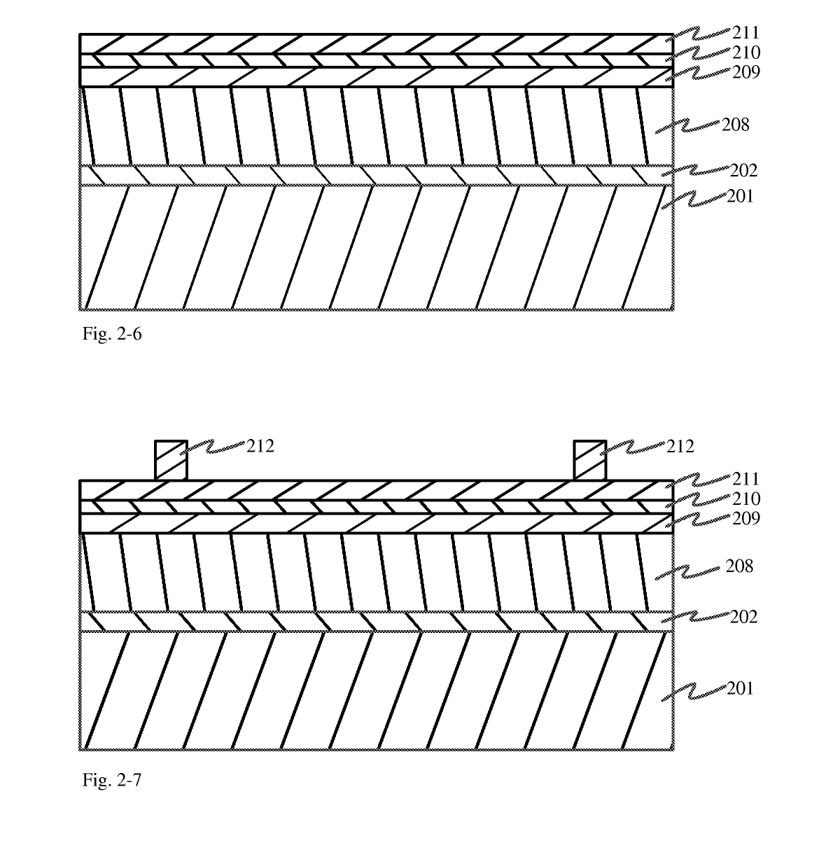

FIGS. 1a and 1b show a side view of one of the embodiments for fabricating a p-type semiconductor thin film Cu(InGa)Se₂ or Cu(InGa)(SeS)₂ on a moving metallized substrate and a n-type semiconductor thin film CdS on the p-type semiconductor thin film Cu(InGa)Se₂ or Cu(InGa)(SeS)₂ using a roll-to-roll process. The roll-to-roll fabrication process shown in FIGS. 1a and 1b comprises units for sequentially electroplating a stack of Cu/In/Cu/Ga—Se/Se-alloy on a moving metallized substrate, an in line thickness measurement system, a electroplating parameters controlling system, a selenization system, and a CdS deposition system. The section 100 shown in FIG. 1a is an electroplating parameters controlling system. The section 110 in FIG. 1a is a roll of the metallized substrate before electroplating. Its cross sectional view is shown in FIG. 2-1 wherein 201 is a substrate, 202 is a back contact electrode, and 203 is a seed layer of copper. The section 120A is the first copper electroplating unit. The section 130 shown in FIG. 1a is an indium electroplating unit. The section 120B shown in FIG. 1a is the second copper electroplating unit. The section 140 shown in FIG. 1a is a Ga—Se alloy electroplating unit. The Ga—Se alloy may be electroplated in a solution that contains gallium ions, selenium ions, and a complexing agent or agents. The section 150 shown in FIG. 1a is a Se-alloy electroplating unit. The Se-alloy is a material that comprises selenium element and a metal element or metals elements or electric conductor particles. The Se-alloy may be electroplated in a solution comprising of selenium ions, metal ions or metals ions or electric conductor particles, and a complexing agent or agents. The section 160 shown in FIG. 1b is a system for measuring the thickness of each layer of the sequentially electroplated stack. The section 170 shown in FIG. 1b is a selenization unit to form a Cu(InGa)Se₂ or Cu(InGa)(SeS)₂ semiconductor thin film. The section 180 shown in FIG. 1b is a system for chemically depositing a n-type semiconductor thin film CdS on the p-type semiconductor thin film Cu(InGa)Se₂ or Cu(InGa)(SeS)₂. The section 190 shown in FIG. 1b is a roll of the metallized substrate with the p-type semiconductor thin film Cu(InGa)Se₂ or Cu(InGa)(SeS)₂ and a n-type semiconductor thin film CdS.

By using the process shown in FIGS. 1a and 1b, a p-type semiconductor thin film Cu(InGa)Se₂ or Cu(InGa)(SeS)₂ may be fabricated on a roll-to-roll moving metallized substrate followed by fabricating a n-type semiconductor thin film on the p-type semiconductor thin film.

The first step of the fabrication is to electroplate a stack such as Cu/In/Cu//Ga—Se/Se-alloy on a metallized substrate as shown in FIG. 1a from the section 110 to section 150. It should be understood that the FIG. 1a just shows one of the embodiments. The different stack may be electroplated by changing the order of the copper, indium, Ga—Se, and Se-alloy electroplating baths or adding an electroplating bath or baths to the system. For example, by removing or skipping the second copper electroplating bath 120B, the sequentially electroplated stack will be Cu/In/Ga—Se/Se-alloy. By changing the order of the indium electroplating unit 130 and Ga—Se electroplating unit 140, the sequentially electroplated stack will be Cu/Ga—Se/Cu/In/Se-alloy, et al. By changing the order of the electroplating bath or adding electroplating bath or baths in the fabrication line, the following stacks may be electroplated: Cu/In/Cu//Ga—Se/Se-alloy, Cu/In/Ga—Se/Se-alloy, Cu/Ga—Se/In/Se-alloy, Cu/In/Cu/Ga—Se/Se-alloy, Cu/Se-alloy/In/Ga—Se, Cu/Se-alloy/Ga—Se/In, In/Cu/Ga—Se/Se-alloy, In/Ga—Se/Cu/Se-alloy, In/Se-alloy/Cu/Ga—Se, In/Se-alloy/Ga—Se/Cu, Ga—Se/Cu/In/Se-alloy, Ga—Se/In/Cu/Se-alloy, Ga—Se/Se-alloy/Cu/In, Ga—Se/Se-alloy/In/Cu, Se-alloy/Cu/In/Ga—Se, Se-alloy/In/Cu/Ga—Se, Se-alloy/Ga—Se/In/Cu, Se-alloy/In/Ga—Se/Cu

By adding copper ions to the Ga—Se electroplating bath, the Ga—Se—Cu alloy may be electroplated. It should be pointed out that the gallium melting point is 28.9C and it could be further reduced as low as 15.3C by forming alloy with indium. Therefore, the material may become liquid when electroplating pure gallium on indium or electroplating indium on pure gallium if the environment temperature is over 15.3C. The melting of the electroplated gallium/indium can cause uniformity issue or forming bumps. In order to avoid this problem, one approach is to control the environment temperature including the plating baths below 15.3C. But this approach has a limitation for the operation. For example, it costs energy to control the environment temperature below 15.3C. The present invention provides a method that is to add small amount of copper ions and selenium ions to the gallium electroplating bath so that the Ga—Cu—Se alloy is electrodeposited. By adding 1% of the copper to the gallium, the melting point could be increased from 28.9C to around 100C. This will not only make the manufacturing process easy control but also improve the inter-diffusion between the elements within a stack in the thermal annealing. The present invention provides a method to electroplate Ga—Se—Cu alloy in an aqueous solution comprising of gallium ions, selenium ions, copper ions, and a complexing agent or agents. By using a Ga—Se—Cu alloy electroplating bath instead of a Ga—Se electroplating bath, the following stacks may be electroplated: Cu/In/Cu//Ga—Se—Cu/Se-alloy, Cu/In/Ga—Se—Cu/Se-alloy, Cu/Ga—Se—Cu/In/Se-alloy, Cu/Se-alloy/In/Ga—Se—Cu, Cu/Se-alloy/Ga—Se—Cu/In, In/Cu/Ga—Se—Cu/Se-alloy, In/Ga—Se—Cu/Cu/Se-alloy, In/Se-alloy/Cu/Ga—Se—Cu, In/Se-alloy/Ga—Se—Cu/Cu, Ga—Se—Cu/In/Cu/Se-alloy, Ga—Se—Cu/Cu/In/Se-alloy, Ga—Se—Cu/Se-alloy/In/Cu, Ga—Se—Cu/Se-alloy/Cu/In, Se-alloy/In/Ga—Se—Cu/Cu, Se-alloy/Ga—Se—Cu/In/Cu, Se-alloy/Cu/In/Ga—Se—Cu, Se-alloy/Cu/Ga—Se—Cu/In

Referring now to section 160 shown in FIG. 1b, a thin film thickness measurement system consists of 160A and 160B. The 160A is a drying and temporary storage unit. The 160B is a XRF measurement unit used for in-line measurement of each layer of the electroplated stack. In order to accurately measure the thickness of each layer of the sequentially electroplated stack using XRF technique, the surface of the stack must be drying without water because the water layer on the surface can affect the accuracy of the measurement. It should be understood that the XRF takes minutes to measure the stack such as Cu/In/Cu/Ga—Se/Se-alloy. Therefore, if the XRF is located a fixed position to measure the stack on a moving substrate in roll-to-roll fabrication line, the data measured is an average result. As shown in FIG. 3, the XRF measurement starts at position 302 as shown in FIG. 3a and ends at position 303 as shown in FIG. 3b, the measured result is an average thickness between the position 302 and position 303. The distance between the position 302 and position 303 is related to the substrate moving speed and the time of the XRF measurement.

In order to control the electroplating parameters, an accurately thickness measurement in a position or positions is needed. The present invention provides a method to accurately measure the thickness of each layer of the sequentially electroplated stack.

The present invention provides a method to use a travelable XRF or travelable XRFs to measure the thickness of each layer of the sequential electroplated stack at one position or multiple positions. The XRFs means multiple XRF. It should be understood that after the electroplating, there is a water layer on the surface of the electroplated stack. The water layer affects the XRF measurement accuracy and should be removed. The section 160A has a heating set-up 162, a gas 164 such as nitrogen or argon gas, and a roller 163. When the substrate with the electroplated stack is moved through the section 160A, the water is removed by turning on the heaters and flowing in gas. The roller 163 can be moved up or down to storage or release the flexible substrate with the electroplated stack. After drying, the electroplated stack is then moved to section 160B where the thickness of each layer of the stack is measured by using travelable XRF or XRFs.

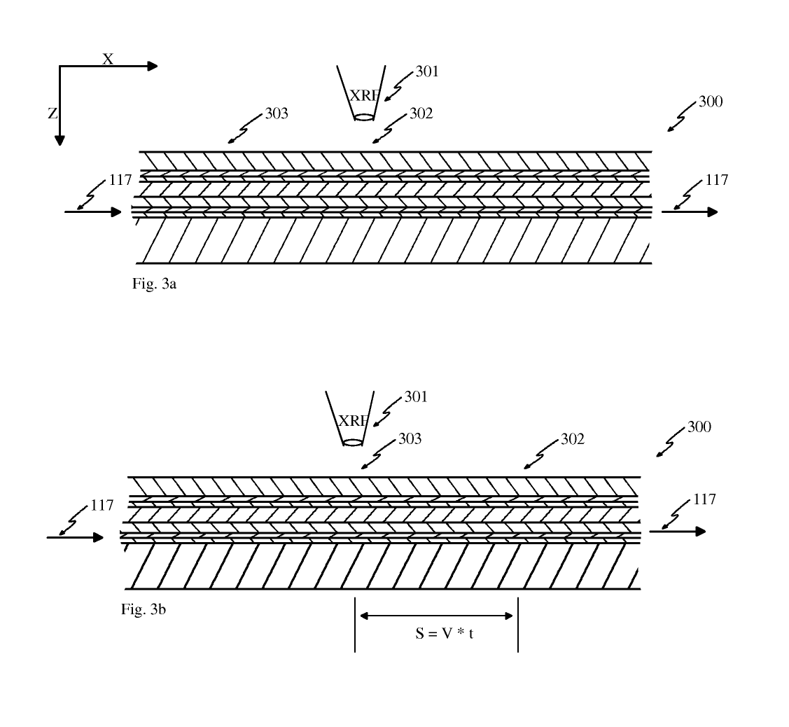

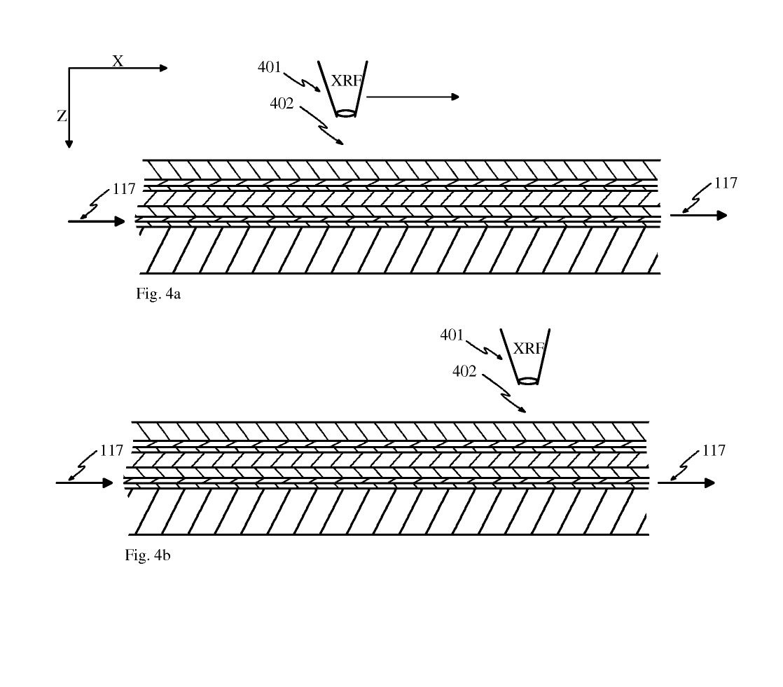

FIGS. 4a and 4b show the thickness measurement in the position 402 using a travelable XRF. The XRF starts the measurement at the position 402 as shown in FIG. 4a and ends at same position as shown in FIG. 4b because the XRF moves at same speed as substrate with the electroplated stack in the same direction during the measurement so that it always focuses on the position 402. The thickness of each layer of the stack such as Cu/In/Cu/Ga—Se/Se-alloy is measured from the position 402. It should be understood that the XRF measures the top layer Se-alloy of the stack Cu/In/Cu/Ga—Se/Se-alloy first, and then continue to penetrate the Se-alloy layer to measure the Ga—Se layer which is under the Se-alloy layer, and then continue to measure the copper layer which is under the Ga—Se layer, and then continue to measure the indium layer which is under the copper layer, and finally measure the copper layer which is under the In layer. After the measurement, the XRF is moved back to the home position and may start the next measurement. The measured data is feed backed to the controlling system 100 to adjust the electroplating parameters and baths compositions.

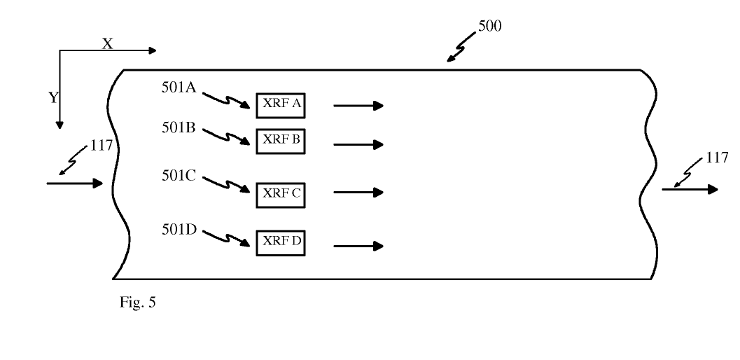

It should be understood that multi-positions measurement may be employed based on the present invention. FIG. 5 shows the thickness measurement in four positions using multiple XRFs. As shown in FIG. 5, four XRFs are moved to the positions where the thickness is being measured. The travelable XRFs move at same speed as the substrate in the same direction during the measurement so that they always focus on the positions where they are started. After the measurement, the XRFs are moved back to the home position and may start the next measurement. The measured data is feed backed to the controlling system 100 to adjust the electroplating parameters and baths compositions. It should be understood that the substrate moving speed in the section 160B during the XRF measurement may be adjusted by moving the roller 163 in section 160A up or down. By moving the roller 163 up, the moving speed of the substrate in section 160B during the XRF measurement may be decreased. After the measurement, the roller 163 is moved down to release the stored material.

Referring now to the section 120A shown in the FIG. 1a, it's the first copper electroplating unit. It is consisted of a pre-cleaning unit 127, a copper electroplating tank 121, a solution storage tank 125, and a post plating rinsing unit 126. The pre-clean unit 127 is to clean the metallized substrate before copper electroplating. The metallized substrate may be cleaned with a hot alkaline solution and then followed by DI water rinsing, and then may be cleaned with a dilute acid solution followed by DI water rinsing again. The substrate after cleaning is then moved to the copper electroplating tank 121 where copper is electroplated on the metallized substrate. The copper electroplating tank is consisted of a tank 121, an anode 123, and a solution 122. After the copper electroplating, the substrate is moved out of the copper bath 121 followed by DI water rinsing in the unit 126. The chemical compositions, pH, and temperature of the solution in the copper electroplating tank 121 and the storage tank 125 are monitored by a controlling system 100. The electroplating tank 121 is connected to the storage tank 125 through the pipe 124 and the solution 122 is circulated between them. The chemical materials are continually added to the storage tank 125 to compensate the consumption of the materials during the electroplating. The storage tank 125 is 2-30 times larger than the electroplating tank 121 so that the consumption of the material during the electroplating causes a little change of the solution concentration. The copper thickness measured from the system 160 is feed backed to the controlling system 100. If the measured data is out of the target thickness, the controlling system 100 will send signal to adjust the copper electroplating parameters until the thickness is within the spec. The operation for the second copper electroplating section 120B is similar with the 120A except that the target electroplated copper thickness may be different.

Referring now to the section 130 shown in the FIG. 1a, it's the indium electroplating unit. It is consisted of an indium electroplating tank 131, a solution storage tank 135, and a post plating rinsing unit 136. The substrate after copper electroplating is moved to the indium electroplating tank 131 where indium is electroplated on the copper surface 112. The indium electroplating tank is consisted of a tank 131, an anode 133, and solution 132. After the indium electroplating, the substrate is moved out from the bath 131 followed by DI water rinsing in the section 136. The chemical compositions, pH, and temperature of the solution in the indium electroplating tank 131 and the storage tank 135 are monitored by a controlling system. The electroplating tank 131 is connected to the storage tank 135 through a pipe 134 so that the solution 132 is circulated between them. The chemical materials are continually added to the storage tank 135 to compensate the consumption of the materials during the electroplating. The storage tank 135 is 2-30 times larger than the electroplating tank 131 so that the consumption of the material during the electroplating causes a little change of the solution concentration. The indium thickness measured from the system 160 is feed backed to the controlling system 100. If the measured data is out of the target thickness, the controlling system 100 will send signal to adjust the indium electroplating parameters until the thickness is within the spec.

Referring now to the section 140 shown in the FIG. 1a, it's the Ga—Se alloy electroplating unit. It is consisted of a Ga—Se electroplating tank 141, a solution storage tank 145, and a post plating rinsing unit 146. The substrate after second copper electroplating is moved to the Ga—Se electroplating tank 141 where Ga—Se alloy is electroplated on the copper surface 114. The Ga—Se electroplating tank is consisted of a tank 141, an anode 143, and the solution 142. After the Ga—Se electroplating, the substrate is moved out from the bath 141 followed by DI water rinsing in the tank 146. The chemical compositions, pH, and temperature of the solution in the indium electroplating tank 141 and the storage tank 145 are monitored by a controlling system 100. The electroplating tank 141 is connected to the storage tank 145 through the pipe 144 so that the solution 142 is circulated between them. The chemical materials are continually added to the storage tank 145 to compensate the consumption of the materials during the electroplating. The storage tank 145 is 2-30 times larger than the electroplating tank 141 so that the consumption of the material during the electroplating causes a little change of the solution concentration. The Ga—Se thickness measured from the system 160 is feed backed to the controlling system 100. If the measured data is out of the target thickness, the controlling system 100 will send signal to adjust the Ga—Se electroplating parameters until the thickness is within the spec.

The Ga—Se alloy is electroplated in an aqueous solution that contains gallium ions, selenium ions, and a complexing agent or agents. The gallium ions may be formed by adding one or more gallium salts to the solution such as gallium chloride, gallium nitride, gallium sulfate, gallium acetate, and gallium nitrate but not limited. The selenium ions may be formed by adding a selenium compound or compounds selected from the group consisting of Selenium acid (H₂SeO₄), Selenous acid (H₂SeO₃), Selenium dioxide (SeO₂), Selenium trioxide (SeO₃), Selenium bromide (Se₂Br₂), Selenium chloride (Se₂Cl₂), Selenium tetrabromide (SeBr₄), Selenium tetrachloride (SeCl₄), Selenium tetrafluoride (SeF₄), Selenium hexafluoride (SeF₆), Selenium oxybromide (SeOBr₂), Selenium oxychloride (SeOCl₂), Selenium oxyfluoride (SeOF₂), Selenium dioxyfluoride (SeO₂F₂), Selenium sulfide (Se₂S₆), and Selenium sulfide (Se₄S₄). The complexing agent or agents may be added to the solution selected from the group consisting of Glucoheptonic acid sodium salt (C₇H₁₃NaO₈), polyethylene glycol (C₂H₄O)ₙH₂O, sodium lauryl sulfate (C₁₂H₂₅SO₄Na), sodium ascorbate (C₆H₇O₆Na), sodium salicylic (C₇H₅NaO₃), and glycine (C₂H₅NO₂). The pH of the solution may be varied between 8 and 14. The electroplating temperature may be varied from 15 and 28C.

It should be understood that Ga—Se—Cu alloy may be electrodeposited in section 140 by adding copper ions to the bath 141. In this case, the solution contains gallium ions, selenium ions, copper ions, and at least one of the complexing agents. The copper ions may be formed by adding a copper salt or copper salts to the solution.

Referring now to the section 150 shown in the FIG. 1, it's the Se-alloy electroplating unit. It is consisted of a Se-alloy electroplating tank 151, a solution storage tank 155, and a post plating rinsing unit 156. The substrate after Ga—Se electroplating is moved to the Se-alloy electroplating tank 151 where Se-alloy is electroplated on the Ga—Se surface 115. The Se-alloy electroplating unit comprises a tank 151, an anode 153, and the solution 152. After the Se-alloy electroplating, the substrate is moved out of the bath 151 followed by DI water rinsing in the unit 156. The chemical compositions, pH, and temperature of the solution in the electroplating tank 151 and the storage tank 155 are monitored by a controlling system 100. The electroplating tank 151 is connected to the storage tank 155 through the pipe 154 so that the solution 152 is circulated between them. The chemical materials are continually added to the storage tank 155 to compensate the consumption of the materials during the electroplating. The storage tank 155 is 2-30 times larger than the electroplating tank 151 so that the consumption of the material during the electroplating causes a little change of the solution concentration. The Se-alloy thickness measured from the system 160 is feed backed to the controlling system 100. If the measured data is out of the target thickness, the controlling system 100 will send signal to adjust the electroplating parameters until the thickness is within the spec.

It should be understood that selenium has three structure forms: amorphous form, monoclinic form, and hexagonal form. The amorphous and monoclinic forms are nonconductor and the hexagonal form is a semiconductor. There is little information for electrodeposition of selenium. A. VON Hippel et al (Reference 8) in their work on the electrodeposition of metallic selenium stated that the current flow is ceased when the thickness is reached an average of 0.05 um. They reported that under a strong illumination, the electroplating could only be continued to 0.12 um before the current flow is ceased. The present invention provides a method to electroplate a conductive selenium layer which is to simultaneously electrodeposit a selenium layer with a metal or metals or electric conductor particles as a Se-alloy so that the electroplating can be continued without interrupt. The metal or metals or electric conductor particles in the Se-alloy may be one of the materials selected from the group consisting of Copper, Indium, Gallium, molybdenum, zinc, chromium, titanium, silver, palladium, platinum, nickel, iron, lead, gold, tin, cadmium, Ru, Os, Ir, Au, and Ge or compounds of these materials.

Based on the present invention, a selenium layer with a metal or metals or electrical conduct particles may be simultaneously electrodeposited from an aqueous solution which contains selenium ions such as (HSeO₃)⁻ and (H₃SeO₃)⁺, one or more metal ions or insoluble electric conductor particles, and a complexing agent or agents. The selenium ions concentration in the solution may be from 0.1M to 7 M. The molar ratio of the metal or metals ions versus selenium ions in the solution may be from 0.005 to 1.0. The concentration of the metal or metals or the electric conductors in the Se-alloy may be from 0.05% to 25% but not limited. The base aqueous solution based on the present invention has selenium ions such as (HSeO₃)⁻ and (H₃SeO₃)⁺ which may be formed by dissolving selenium compound or compounds to water or solution from at least one of the compounds selected from the group comprising of Selenium acid (H₂SeO₄), Selenous acid (H₂SeO₃), Selenium dioxide (SeO₂), Selenium trioxide (SeO₃), Selenium bromide (Se₂Br₂), Selenium chloride (Se₂Cl₂), Selenium tetrabromide (SeBr₄), Selenium tetrachloride (SeCl₄), Selenium tetrafluoride (SeF₄), Selenium hexafluoride

(SeF₆), Selenium oxybromide (SeOBr₂), Selenium oxychloride (SeOCl₂), Selenium oxyfluoride (SeOF₂), Selenium dioxyfluoride (SeO₂F₂), Selenium sulfide (Se₂S₆), and Selenium sulfide (Se₄S₄). The metal ions or metals ions may be formed by adding a metal salt or metal salts to the base solution or adding conductor particles to the base solution. One or more complexing agents may be added to the solution selected from the group consisting of Glucoheptonic acid sodium salt(C₇H₁₃O₈Na), polyethylene glycol (C₂H₄O)ₙH₂O, sodium lauryl sulfate (C₁₂H₂₅SO₄Na), sodium ascorbate (C₆H₇O₆Na), sodium tartrate (Na₂C₄H₄O₆), Glycine (C₂H₅NO₂), sodium citrate (Na₃C₆H₅O₇.2H₂O), and sodium salicylate (C₇H₅NaO₃). The solution pH may be adjusted between 0.5 and 13 by adding an acid solution or an alkaline solution.

For example, in order to deposit an electrical conductive layer of Se—Cu alloy which is consisted of selenium and copper elements, one or more copper salts such as copper chloride (CuCl₂), copper sulfate (CuSO₄), et al may be added to the base solution so that the solution contains selenium ions and copper ions. One or more complexing agents may be added to the solution. The molar ratio between the copper ions and the selenium ions may be varied from 0.005 to 1.0 but not limited. For example, in order to deposit an electrical conductive layer Se—In which is consisted of selenium and indium elements, the indium salt or salts may be added to the base aqueous solution so that the bath contains both the selenium ions and indium ions. The molar ratio between the indium ions and the selenium ions may be varied from 0.005 to 1.0 but not limited. One or more complexing agents may be added to the solution. For example, in order to deposit an electrical conductive layer Se—Ga which is consisted of selenium and gallium elements, the gallium salt or salts may be added to the base aqueous solution so that it contains both the selenium ions and gallium ions. The molar ratio between the gallium ions and the selenium ions may be varied from 0.005 to 1.0 but not limited. One or more complexing agents may be added to the solution. For depositing an electrical conductive layer Se—Cu—In which is consisted of selenium and small amount of copper and indium, the copper salt or salts and indium salt or salts are added to the base aqueous solution so that it contains selenium ions, copper ions, and indium ions, et al.

It should be understood that the insoluble metal compound particles or insoluble electric conductor particles may be added to the base aqueous solution for depositing a conductive Se-alloy layer. When the selenium is electrodeposited, the insoluble particles may be simultaneously deposited due to the molecular absorbing force. The dimension of the insoluble particles may be varied from 0.1 um to 10 um but not limited.

After electrochemically depositing a stack of copper, indium, Ga—Se, and Se-alloy as described above, the part is then thermally treated at a temperature between 400C and 700 C to form a semiconductor thin film as shown in section 170 of the FIG. 1b. The selenization system 170 is consisted of zoon 172, zoon 173, and zoon 174. The zoon 172 has two heaters 172A and 172B which are to quickly heat the electroplated stack to a target temperature. The zoon 173 has heater/cooler 173A and 173B which are to control the temperature. The zoon 174 has coolers 174A and 174B which are to cool down the substrate. The selenization system also has gas enter and exit for gas 175 flows in and out. If the electroplated stack is thermally treated in nitrogen or argon atmosphere, Cu(InGa)Se₂ semiconductor thin film is formed. If it is thermally treated in an atmosphere with S and nitrogen gas, Cu(InGa)(SeS)₂ semiconductor thin film may be formed. It has been found that the solar cell efficiency can be improved by adding S to the semiconductor layer.

After selenization, a n-type semiconductor thin film CdS or ZnS is then deposited on Cu(InGa)Se₂ or Cu(InGa)(SeS)₂ surface to form a p-n junction as shown in FIG. 1b section 180. The CdS or ZnS chemical deposition system is consisted of a pre-clean unit 181, a chemical bath 182, and a post clean unit 184.

The window layers of ZnO/ZnO:Al or ZnO/ITO (indium tin oxide) are then deposited followed by depositing the front metal contactors to form solar cells. The front contact electrodes are then formed by printing process.

The surface 111 in FIG. 1a is the metalized substrate before copper electroplating. The surfaces 112, 113, 114, 115, and 116 in FIGS. 1a are after copper, indium, copper, Ga—Se, and Se-alloy electroplating, respectively. The surface 117 in FIG. 1b is after removing the water from the stack surface. The surface 118 in FIG. 1b is after selenization and the surface 119 in FIG. 1b is after deposition of CdS or ZnS n-type semiconductor thin film.

FIG. 2 shows cross sectional views of the processes for fabricating CIGS solar cells for one of the embodiments based on the present invention. FIG. 2-1 shows a cross sectional view of the metalized substrate comprising of a substrate 201, a back contact electrode 202, and a copper seed layer 203. FIG. 2-2 shows a cross sectional view after electroplating a stack of Cu/In/Cu/Ga—Se/Se—Cu on the metalized substrate. The 204a and 204b in FIG. 2-2 are the first electroplated and second electroplated copper layers, respectively, 205 in FIG. 2-2 is indium layer, 206 in FIG. 2-2 is Ga—Se alloy layer, and 207 is Se—Cu alloy layer. FIG. 2-3 shows a cross sectional view after the selenization, wherein the 201 is a substrate, 202 is a back contact electrode, and 208 is a Cu(InGa)Se₂ or Cu(InGa)(SeS)₂ semiconductor thin film. FIG. 2-4 shows a cross sectional view after chemical deposition of a CdS or ZnS thin film 209. The n-type semiconductor layer of CdS may be deposited using a chemical bath method in an aqueous solution comprising of 0.0015-0.005M CdSO₄, 2.0-3.0 M NH₄OH 2.25, and 0.1-0.3M SC(NH₂)₂ at 50-70C. The alternative n-type semiconductor to CdS may be ZnS which can be deposited from a aqueous chemical bath composition of 0.16 M ZnSO₄, 7.5M ammonia, and 0.6M thiorea at 70-80C. FIG. 2-5 shows a cross sectional view after deposition of the zinc oxide (ZnO) layer 210. The zinc oxide (ZnO) may be deposited using a radio frequency (RF) magnetron sputtering. FIG. 2-6 shows a cross sectional view after deposition of ZnO:Al layer or ITO layer 211. Al-doped ZnO (Al:ZnO) thin films were deposited at 150-300 C by RF-magnetron sputtering and then annealed by a rapid thermal process under different ambient. FIG. 2-7 shows a cross sectional view after forming the front electrodes 212. The front electrodes may be formed by printing silver paste such as Dupont PV410 and PV412.

### Example 1

The substrates used for the tests were stainless steel/Mo/Cu/In/Cu, stainless steel/SiO₂/Mo/Cu/In, and glass/Mo/Cu/In. These substrates have Cu and In surface where Ga—Se alloy is being electroplated. The solutions used for the tests were consisted of gallium chloride (GaCl₃), 0.01 M selenium dioxide (SeO₂), and one of the complexing agents selected from the group comprising of 0.1M Glucoheptonic acid sodium salt (C₇H₁₃NaO₈), 0.1M polyethylene glycol (C₂H₄O)ₙH₂O, 0.15M sodium lauryl sulfate (C₁₂H₂₅SO₄Na), 0.3M sodium ascorbate (C₆H₇O₆Na), 0.25M sodium salicylic (C₇H₅NaO₃), and 0.2M glycine (C₂H₅NO₂). The gallium chloride concentration was 0.15M, 0.35M, 0.50M, 1.0 M, and 2.0M. The pH was adjusted to 10.5, 12.5, and 13.5 respectively. Current density was varied from 5 mA/cm² to 50 mA/cm². Temperature was at 15C, 20C, and 25C. The electroplated Ga—Se alloy thickness was from 300 to 1000 nm. The electroplated Ga—Se surface was dense, bright, and smooth. However, it was found that when gallium chloride concentration was increased to 1.5 M or over, the solution flow-ability was decreased.

### Example 2

The substrates used for the tests were stainless steel/Mo/Cu/In/Cu and stainless steel/Mo/Cu/In. The solutions used for the tests were consisted of 0.25 M gallium chloride (GaCl₃), selenous acid (H₂SO₃), and 0.1 M Glucoheptonic acid sodium salt (C₇H₁₃NaO₈). The concentration of selenous acid (H₂SO₃) was 0.01 M, 0.05M, 0.1M, and 0.25M, respectively. The pH was adjusted to 10.5 and 13.5 respectively. Current density was at 25 mA/cm². Temperature was at 20C. The electroplated Ga—Se alloy thickness was from 300 to 1000 nm. The electroplated Ga—Se surface was dense, bright, and smooth.

### Example 3

The substrates used for the tests were stainless steel/Mo/Cu/In/Cu and stainless steel/Mo/Cu/In. The solutions used for the tests were consisted of 0.25 M gallium chloride (GaCl₃), 0.025 M selenous acid (H₂SO₃), 0.025 M CuCl₂, and 0.1 M Glucoheptonic acid sodium salt (C₇H₁₃NaO₈). The pH was adjusted to 10.5 and 13.5 respectively. Current density was at 25 mA/cm². Temperature was at 20C. The electroplated Ga—Se—Cu alloy thickness was around 500 nm. The electroplated Ga—Se—Cu surface was dense, bright, and smooth.

### Example 4

The aqueous electroplating bath was consisted of 2 M SeO₂, 0.05 M CuCl₂, and 0.1 M Glucoheptonic acid sodium salt (C₇H₁₃NaO₈). The current density was at 15 mA/cm², mA/cm², and 50 mA/cm². The temperature was at 15C, 20C, and 25C, respectively. The pH was 1.75, 8.5, and 11.5, respectively. The anode used for the electroplating was a stainless steel plate. Substrates with indium, copper, and gallium on the top surface where is being electroplated were used for the experimental as: stainless steel/Mo/Cu, stainless steel/Mo/Cu/In, stainless steel/Mo/Cu/In/Ga, stainless steel/Mo/Cu/Ga—Se, stainless steel/Si₃N₄/Mo/Cu, and soda lime glass/Mo/Cu/In/Ga. For stainless steel/Si₃N₄/Mo/Cu, the Si₃N₄ was patterned with partially opening so that the Mo is directly contacted with stainless steel through the opening areas. The Se—Cu alloy was electrodeposited on the above substrates. The results showed that no any interrupt was found with the Se—Cu thickness up to 10 um. The maximum current density can be 50 mA/cm². It was found that the electrodeposited Se—Cu layer has dense surface on indium and gallium surface than on copper surface.

It should be understood that stainless steel is not only material for anode for Se—Cu electroplating. The stable electric conduct materials such as graphite, platinum (Pt), and gold as well as selenium alloy such as Se—Cu alloy may be used as an anode.

### Example 5

The aqueous electroplating bath was consisted of 2 M SeO₂, 0.05M CuCl₂, and 0.1 M polyethylene glycol (PEG). The current density was at 15 mA/cm². The temperature was at 20C. pH was adjusted to 1.75, 8.5, and 11.5, respectively. The anode used for the electroplating was a stainless steel plate. Substrates with indium, copper, and gallium on the top surface where is being electroplated were used for the experimental as: stainless stainless steel/Mo/Cu/In/Ga, stainless steel/Mo/Cu/Ga/In, stainless steel/SiO₂/Mo/Cu, and soda lime glass/Mo/Cu/In/Ga. The results showed that no any interrupt was found with the deposition of Se—Cu thickness up to 10 um. The electrodeposited Se—Cu layer has dense and smooth surface.

### Example 6

The aqueous electroplating bath was consisted of 2 M SeO₂, 0.1M CuCl₂, and 0.6M sodium lauryl sulfate (C₁₂H₂₅SO₄Na). The current density was at 15 mA/cm2. The temperature was at 20C. pH was adjusted to 1.75, 8.5, and 11.5 respectively. The anode used for the electroplating was a stainless steel plate. Substrates with indium and gallium on the top surface where is being electroplated were used for tests, respectively, as: stainless steel/Mo/Cu/In, stainless steel/Mo/Cu/In/Ga, stainless steel/SiO₂/Mo/Cu, and soda lime glass/Mo/Cu/In/Ga. For stainless steel/SiO₂/Mo/Cu, the SiO₂ was patterned with partially opening so that the Mo is directly contacted with stainless steel through the opening areas. The results showed that no any interrupt was found with the deposition of Se—Cu thickness up to 10 um. It was found that the electroplating was successful at the above solutions. The electrodeposited Se—Cu layer has smooth surface.

### Example 7

The base aqueous electroplating bath was consisted of 0.5 M, 2.5 M, and 5 M SeO₂ and 0.1 M Glucoheptonic acid sodium salt (C₇H₁₃NaO₈). Copper salt CuCl₂ was added to the bath with 0.1 g/l, 10 g/l, 50 g/l, and 250 g/l, respectively. The current density was 15 mA/cm² and 50 mA/cm², respectively. The temperature was at 20C. The pH was adjusted to 1.75 and 9.5, respectively. Substrates with indium and gallium on the top surface where is being electroplated were used for tests as: stainless steel/Mo/Cu/In, stainless steel/Mo/Cu/In/Ga and stainless steel/Mo/Cu/Ga/In. The results showed that no any interrupt was found with the deposition of Se—Cu thickness up to 10 um. The electrodeposited Se—Cu layer has dense and smooth surface.

### Example 8

Four aqueous electroplating baths were used for the experimental as:

A. 2 M SeO₂, 0.04M CuSO₄, and 0.1 M Glucoheptonic acid sodium salt (C₇H₁₃NaO₈)
B. 2 M SeO₂, 0.05M InCl₃, and 0.1 M Glucoheptonic acid sodium salt (C₇H₁₃NaO₈)
C. 2 M SeO₂, 0.05M GaCl₃, and 0.1 M Glucoheptonic acid sodium salt (C₇H₁₃NaO₈)
D. 2 M SeO₂, 0.05M CuCl₂, 0.05 M GaCl₃ and 0.1 M Glucoheptonic acid sodium salt (C₇H₁₃NaO₈).

The current density was 15 mA/cm². The temperature was at 20C. The pH was adjusted to 1.75 and 8.5, respectively. The anode used for the electroplating tests was a stainless steel plate. Substrates with indium and gallium on top surface were used for electroplating as: stainless steel/Mo/Cu/In and stainless steel/Mo/Cu/In/Ga. No any interrupt was found in the above solutions with the thickness of electrodeposited layer up to 10 um. It was found that the electrodeposited layers have dense and smooth surface.

### Example 9

The base aqueous electroplating bath was consisted of 2M selenium dioxide (SeO₂) and 0.05M CuCl₂. One complexing agent was added to the solution selected from the group comprising of 0.3 M sodium ascorbate (C₆H₇O₆Na), 0.25 M sodium tartrate (Na₂C₄H₄O₆), 0.3 M Glycine (C₂H₅NO₂), 0.25 M sodium citrate (Na₃C₆H₅O₇.2H₂O), and 0.2 M sodium salicylate (C₇H₅NaO₃). Substrates with indium and gallium on the top surface were used for tests as: stainless steel/Mo/Cu/In and stainless steel/Mo/Cu/In/Ga. The current density was 15 mA/cm² and 50 ma/cm², respectively. The temperature was at 20C. The pH was adjusted to 1.75, and 9.5, respectively. The results showed that no any interrupt was found with the deposition of Se—Cu thickness up to 10 um. It was found that the electrodeposited Se—Cu layer has dense and smooth surface.

### Example 10

Copper, indium, Ga—Se alloy, and Se—Cu alloy were sequentially electroplated as a stack on a metallized substrate. The substrate used for the experimental was stainless steel/Mo/Cu. The Mo thickness was 500 nm and the Cu thickness was 30 nm. Copper, indium, Ga—Se alloy, and Se—Cu alloy were sequentially deposited on the substrate. The copper electroplating bath was a cyanide-free alkaline copper plating solution. The current density was varied from 10 mA/cm2 to 25 mA/cm2. The electroplated copper thickness was 400 nm.

The indium bath used for the electroplating was consisted of indium sulfamate, sodium sulfamate, sulfamic acid, sodium chloride, and triethanolamine with a pH of about 1.5. The current density was varied from 5 mA/cm2 to 50 mA/cm2. Anode was a pure indium plate. The temperature was at 15C, 20C, and 28C. The electrodeposited indium thickness was around 800 nm.

The aqueous Ga—Se electroplating bath was consisted of 0.25 M gallium chloride (GaCl₃), 0.01 M selenous acid (H₂SeO₃), and 0.1 M Glucoheptonic acid sodium salt (C₇H₁₃NaO₈). The temperature was at 15C, 20C, and 28C, respectively. The electroplated Ga—Se thickness was around 200 nm.

The aqueous Se—Cu alloy electroplating bath was consisted of 2 M SeO₂, 0.05 M CuCl₂, and 0.1 M Glucoheptonic acid sodium salt (C₇H₁₃NaO₈). The current density was 15 mA/cm2. The temperature was 20C. The pH was 1.75. The anode used for the electroplating was a stainless steel plate. The electroplated Se—Cu thickness was around 1350 nm.

The following stacks were sequentially electroplated:

### Cu/In/Ga—Se/Se—Cu

### Cu/Ga—Se/In/Se—Cu

### Cu/In/Cu/Ga—Se/Se—Cu

### In/Cu/Ga—Se/Se—Cu

### Cu/In/Se—Cu/Ga—Se,

### Cu/Ga—Se/Se—Cu/In,

### Cu/Se—Cu/In/Ga—Se,

### Cu/Se—Cu/Ga—Se/In,

The above electroplated stacks were selenized at 500-600C to form a Cu(InGa)Se₂ semiconductor thin film.

What is claimed is:

1. A method of fabricating solar cells using a continuous roll-to-roll system, wherein continuously moving substrate through the units to deposit back contact electrode, electroplate copper, indium, gallium alloy, and selenium alloy for fabricating CIGS thin film solar cells, comprising steps of:
depositing a back contact electrode on substrate;
sequentially electroplating a stack comprising of at least one layer of copper, at least one layer of indium, at least one layer of gallium alloy, and at least one layer of selenium alloy;
measuring and controlling the thickness of each stack layers
thermally treatmenting the electroplated stack at a high temperature to form a p-type semiconductor thin film comprising of copper, indium, gallium, selenium, and sulphur;
depositing a n-type semiconductor layer on the p-type semiconductor layer to form p-n junction
depositing transparent conductive window layers on the n-type semiconductor layer
forming front electrodes

2. The method of claim 1, wherein the substrates is selected from the group comprising of soda lime glass, aluminum, stainless steel, titanium, molybdenum, steel, polyimide, Teflon, and brass, stainless steel/SiO₂, and stainless steel/Si₃N₄.

3. The method of claim 1, wherein the back contact electrode is one of the materials selected from the group consisting of Ti—Cu alloy, Cr—Cu alloy, W—Cu alloy, Mo—Cu alloy, Mo, W, Ti—W alloy, Ti/Pd, Ti/Pt, Mo/Cu, Cr/Pd, Ti/Ag, Ti/Cu, Cr/Cu, SiO₂/Mo, Si₃N₄/Mo, and Ti/Au.

4. The method of claim 1, wherein the sequentially electroplated stack on the back contact electrode is selected from the group consisting of Cu/In/Ga—Se/Se-alloy, Cu/Ga—Se/In/Se-alloy, Cu/In/Cu/Ga—Se/Se-alloy, Cu/Se-alloy/In/Ga—Se, Cu/Se-alloy/Ga—Se/In, In/Cu/Ga—Se/Se-alloy, In/Ga—Se/Cu/Se-alloy, In/Se-alloy/Cu/Ga—Se, In/Se-alloy/Ga—Se/Cu, Ga—Se/Cu/In/Se-alloy, Ga—Se/In/Cu/Se-alloy, Ga—Se/Se-alloy/Cu/In, Ga—Se/Se-alloy/In/Cu, Se-alloy/Cu/In/Ga—Se, Se-alloy/In/Cu/Ga—Se, Se-alloy/Ga—Se/In/Cu, Se-alloy/In/Ga—Se/Cu, Cu/In/Ga—Se—Cu/Se-alloy, Cu/Ga—Se—Cu/In/Se-alloy, Cu/Se-alloy/In/Ga—Se—Cu, Cu/Se-alloy/Ga—Se—Cu/In, In/Cu/Ga—Se—Cu/Se-alloy, In/Ga—Se—Cu/Cu/Se-alloy, In/Se-alloy/Cu/Ga—Se—Cu, In/Se-alloy/Ga—Se—Cu/Cu, Ga—Se—Cu/In/Cu/Se-alloy, Ga—Se—Cu/Cu/In/Se-alloy, Ga—Se—Cu/Se-alloy/In/Cu, Ga—Se—Cu/Se-alloy/Cu/In, Se-alloy/In/Ga—Se—Cu/Cu, Se-alloy/Ga—Se—Cu/In/Cu, Se-alloy/Cu/In/Ga—Se—Cu, Se-alloy/Cu/Ga—Se—Cu/In.

5. The method according to claim 4, wherein the Ga—Se alloy is electroplated in an aqueous solution comprising of gallium ions, selenium ions, and a complexing agent.

6. The aqueous solution according to claim 5, wherein the gallium ions is formed by adding at least one of the gallium salts to the aqueous solution consisting of gallium chloride, gallium nitride, gallium sulfate, gallium acetate, and gallium nitrate.

7. The aqueous solution according to claim 5, wherein the gallium ions concentration is between 0.1M and 3.0 M.

8. The aqueous solution according to claim 5, wherein the selenium ions is formed by adding at least one of the compounds to the solution consisting of Selenium acid (H₂SeO₄), Selenous acid (H₂SeO₃), Selenium dioxide (SeO₂), and Selenium trioxide (SeO₃).

9. The aqueous solution according to claim 5, wherein the selenium ions concentration is between 0.05 and 0.2M

10. The aqueous solution according to the claim 5, wherein the complexing agent is at least one of Glucoheptonic acid sodium salt (C₇H₁₃NaO₈), polyethylene glycol (C₂H₄O)ₙH₂O, sodium lauryl sulfate (C₁₂H₂₅SO₄Na), sodium ascorbate (C₆H₇O₆Na), sodium salicylic (C₇H₅NaO₃), and glycine (C₂H₅NO₂).

11. The aqueous solution according to the claim 5, wherein the pH of the solution is between 10 and 14.

12. The aqueous solution according to the claim 5, wherein the electroplating temperature is between 15C and 28C.

13. The method according to claim 4, wherein Ga—Se—Cu alloy is electroplated in an aqueous solution comprising of gallium ions, selenium ions, copper ions, and a complexing agent selected from the group consisting of Glucoheptonic acid sodium salt (C₇H₁₃NaO₈), polyethylene glycol (C₂H₄O)ₙH₂O, sodium lauryl sulfate (C₁₂H₂₅SO₄Na), sodium ascorbate (C₆H₇O₆Na), sodium salicylic (C₇H₅NaO₃), and glycine (C₂H₅NO₂).

14. The method of claim 4, wherein the Se-alloy is selected from the group consisting of Se—Ge alloy, Se—Pb alloy, Se—Fe alloy, Se—Ni alloy, Se—Cu alloy, Se—Pt alloy, Se—In alloy, Se—Pd alloy, Se—Ga alloy, Se—Ag alloy, Se—Ti alloy, Se—Cr alloy, and Se—Zn alloy.

15. The method according to claim 4, wherein the Se-alloy is electroplated in an aqueous solution comprising of selenium ions, ions of at least one metal element, and at least one of the complexing agents.

16. The aqueous electroplating solution according to the claim 15, wherein the concentration of the selenium ions is between 0.1 M and 7.0 M.

17. The aqueous electroplating solution according to the claim 15, wherein the metal ions comprises at least one of molybdenum ions, zinc ions, chromium ions, copper ions, titanium ions, silver ions, palladium ions, nickel ions, indium ions, gold ions, gallium ions, tin ions, cadmium ions, and germanium ions.

18. The aqueous electroplating solution according to the claim 15, wherein the molar ratio of the metal ions to selenium ions is between 0.05 and 1.0.

19. The aqueous electroplating solution according to the claim 15, wherein the complexing agent is at least one of Glucoheptonic acid sodium salt(C₇H₁₃O₈Na), polyethylene glycol (C₂H₄O)ₙH₂O, sodium lauryl sulfate (C₁₂H₂₅SO₄Na), sodium ascorbate (C₆H₇O₆Na), sodium tartrate (Na₂C₄H₄O₆), Glycine (C₂H₅NO₂), sodium citrate (Na₃C₆H₅O₇.2H₂O), and sodium salicylate (C₇H₅NaO₃).

20. The aqueous electroplating solution according to the claim 15, wherein the pH of the solution is between 0.5 and 11.5.

21. The aqueous electroplating solution according to the claim 15, wherein temperature of the solution is between 10 C and 50 C.

22. The method of claim 1, wherein thermally treatmenting the electroplated stack to form a semiconductor compound is performed at a temperature between 400C and 700C at atmosphere comprising at least one of sulfur gas, nitrogen gas, and argon gas.

23. The method of claim 1, wherein measuring and controlling thickness of each stack layers are performed in systems comprising of a drying unit, a travelable XRF measurement unit, and a controlling unit.

24. The drying unit according to the claim 23, wherein there is a hot gas zone where the water on electroplated stack is removed before going to travelable XRF measurement system for thickness measurement.

25. The travelable XRF measurement unit according to claim 24, wherein a XRF or multiple XRFs is or are moved at same speed with the measuring target of the substrate during the measurement.

26. The method of claim 23, wherein the measured result from the travelable XRF measurement unit is sent to the controlling unit where the parameters such as electroplating current, temperature, solution composition, and substrate moving speed are adjusted based on the XRF measurement result until the thickness of the electroplated stack meet the target.
